(19) United States
(12) Patent Application Publication
(10) Pub. No.: US 2018/0190661 A1
(43) Pub. Date: Jul. 5, 2018

(54) SEMICONDUCTOR DEVICE AND METHOD FOR FABRICATING THE SAME

(71) Applicants: UNITED MICROELECTRONICS CORP., Hsin-Chu City (TW); Fujian Jinhua Integrated Circuit Co., Ltd., Quanzhou City (CN)

(72) Inventors: Yung-Ming Wang, Taichung City (TW); Li-Wei Liu, Kaohsiung City (TW); Shu-Yen Chan, Changhua County (TW); Yukihiro Nagai, Saijo City (JP); Tien-Chen Chan, Tainan City (TW); Ger-Pin Lin, Tainan City (TW)

(21) Appl. No.: 15/854,816

(22) Filed: Dec. 27, 2017

(30) Foreign Application Priority Data
Dec. 29, 2016 (CN) 201611249424.7

(51) Int. Cl. H01L 27/108; H01L 21/28; H01L 29/423; H01L 29/49

(52) U.S. Cl. CPC H01L 27/10876; H01L 21/2822; H01L 21/28088; H01L 29/4966; H01L 29/4236; H01L 29/42368; H01L 27/10823

(57) ABSTRACT

A method for fabricating semiconductor device includes the steps of: forming a trench in a substrate; performing an ion implantation process to implant ions into the substrate underneath the trench; performing an in-situ steam generation (ISSG) process to form a gate dielectric layer in the trench; forming a gate electrode on the gate dielectric layer; and forming a doped region in the substrate adjacent to two sides of the gate electrode.

### BACKGROUND OF THE INVENTION

### 1. Field of the Invention

The invention relates to a method for fabricating semiconductor device, and more particularly to a method for fabricating a dynamic random access memory (DRAM) device.

### 2. Description of the Prior Art

As electronic products develop toward the direction of miniaturization, the design of dynamic random access memory (DRAM) units also moves toward the direction of higher integration and higher density. Since the nature of a DRAM unit with buried gate structures has the advantage of possessing longer carrier channel length within a semiconductor substrate thereby reducing capacitor leakage, it has been gradually used to replace conventional DRAM unit with planar gate structures.

Typically, a DRAM unit with buried gate structure includes a transistor device and a charge storage element to receive electrical signals from bit lines and word lines. Nevertheless, current DRAM units with buried gate structures still pose numerous problems due to limited fabrication capability. Hence, how to effectively improve the performance and reliability of current DRAM device has become an important task in this field.

### SUMMARY OF THE INVENTION

According to an embodiment of the present invention, a method for fabricating semiconductor device includes the steps of: forming a trench in a substrate; performing an ion implantation process to implant ions into the substrate underneath the trench; performing an in-situ steam generation (ISSG) process to form a gate dielectric layer in the trench; forming a gate electrode on the gate dielectric layer; and forming a doped region in the substrate adjacent to two sides of the gate electrode.

According to another aspect of the present invention, a semiconductor device includes: a gate electrode in a substrate; a doped region in the substrate adjacent to two sides of the gate electrode; and a gate dielectric layer between the gate electrode and the doped region. Preferably, the gate dielectric layer above the doped region comprises a first thickness and the gate dielectric layer under the doped region comprises a second thickness.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 illustrates a top-view for fabricating a DRAM device according to an embodiment of the present invention.

FIG. 2 illustrates a cross-sectional view of the DRAM device along the sectional line AA′ of FIG. 1.

### DETAILED DESCRIPTION

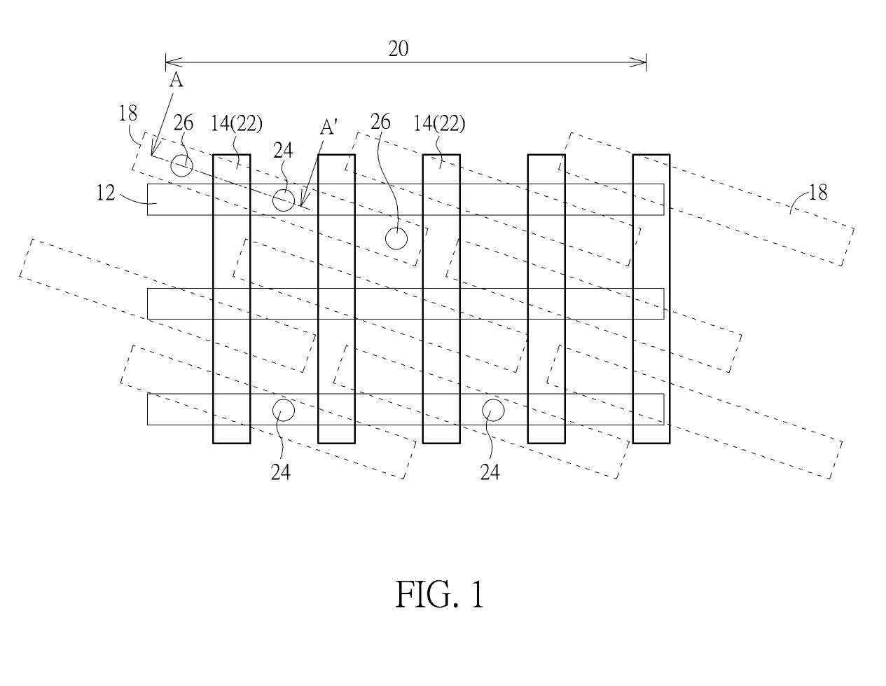

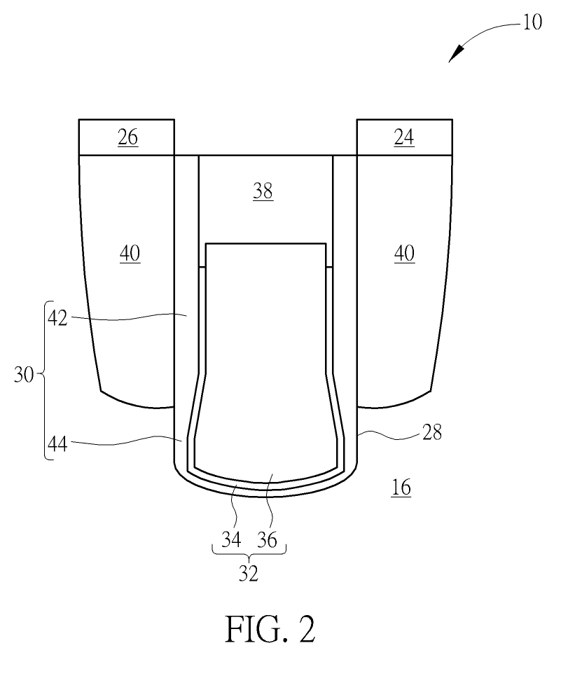

Referring to FIGS. 1-2, FIGS. 1-2 illustrate a method for fabricating a DRAM device according to an embodiment of the present invention, in which FIG. 1 illustrates a top-view for fabricating the DRAM device and FIG. 2 illustrates a cross-sectional view of the DRAM device along the sectional line AA′ of FIG. 1. Preferably, the present embodiment pertains to fabricate a memory device, and more particularly a DRAM device 10, in which the DRAM device 10 includes at least a transistor device (not shown) and at least a capacitor structure (not shown) that will be serving as a smallest constituent unit within the DRAM array and also used to receive electrical signals from bit lines 12 and word lines 14.

As shown in FIG. 1, the DRAM device 10 includes a substrate 16 such as a semiconductor substrate or wafer made of silicon, a shallow trench isolation (STI) 24 formed in the substrate 16, and a plurality of active areas (AA) 18 defined on the substrate 16. A memory region 20 and a periphery region (not shown) are also defined on the substrate 16, in which multiple word lines 14 and multiple bit lines 12 are preferably formed on the memory region 20 while other active devices (not shown) could be formed on the periphery region. For simplicity purpose, only devices or elements on the memory region 20 are shown in FIG. 1 while elements on the periphery region are omitted.

In this embodiment, the active regions 18 are disposed parallel to each other and extending along a first direction, the word lines 14 or multiple gates 22 are disposed within the substrate 16 and passing through the active regions 18 and STIs 24. Preferably, the gates 22 are disposed extending along a second direction, in which the second direction crosses the first direction at an angle less than 90 degrees.

The bit lines 12 on the other hand are disposed on the substrate 16 parallel to each other and extending along a third direction while crossing the active regions 18 and STI 24, in which the third direction is different from the first direction and orthogonal to the second direction. In other words, the first direction, second direction, and third direction are all different from each other while the first direction is not orthogonal to both the second direction and the third direction. Preferably, contact plugs such as bit line contacts (BLC) (not shown) are formed on the active regions 18 adjacent to two sides of the word lines 14 to electrically connect to source/drain region (not shown) of each transistor element and storage node contacts (not shown) are formed to electrically connect to a capacitor.

The fabrication of word lines 14 (or also referred to as buried word lines) is explained below. As shown in FIG. 2, at least a trench 28 is first formed in the substrate 16 on the memory region 20, and an ion implantation process is conducted to implant ions into the substrate 16 directly under the trench 28 to alter the property of the bottom surface of the trench 28. According to an embodiment of the present invention, the ions could also be implanted not only in the substrate 16 directly underneath the trench 28 but also in the substrate 16 adjacent to two sides of the trench 28 and close to the bottom of the trench 28. In this embodiment, the ions implanted into the substrate 16 includes but not limited to for example oxygen ions and/or nitrogen ions.

Next, an in-situ steam generation (ISSG) process is conducted to form a gate dielectric layer 30 made of silicon oxide in the trench 28. In this embodiment, the temperature of the ISSG process is between 1000° C. to 1050° C. and the pressure of the ISSG process is between 5 Torr to 20 Torr. The flow volume of the oxygen of the ISSG process on the other hand is between 10 standard liter per minute (slm) to 50 slm.

Next, a gate electrode 32 is formed on the gate dielectric layer 30. Preferably, the formation of the gate electrode 32 could accomplished by sequentially depositing a conductive layer 34 on the surface of the gate dielectric layer 28 and a metal layer 36 on the conductive layer 34, and then conducting an etching process to remove part of the metal layer 36 and part of the conductive layer 34 to form a gate electrode 32 on the gate dielectric layer 30, in which the top surface of the remaining metal layer 36 is even with the top surface of the conductive layer 34 at this stage. Next, part of the conductive layer 34 could be removed so that the top surface of the conductive layer 34 is slightly lower than the top surface of the metal layer 36. In this embodiment, the conductive layer 34 is preferably made of titanium nitride (TiN) and the metal layer 36 is made of titanium (Ti) or tungsten (W), but not limited thereto. Next, a hard mask 38 made of dielectric material including but not limited to for example silicon nitride is formed on the gate electrode 32, in which the top surface of the hard mask 38 is even with the top surface of the gate dielectric layer 30 and the substrate 16. This completes the fabrication of a buried word line according to an embodiment of the present invention.

Next, an ion implantation process could be conducted depending on the demand of the process to form a doped regions 40 such as lightly doped drain or source/drain region in the substrate 16 adjacent to two sides of the gate electrode 32. Next, a contact plug process could be conducted to form word line contacts 24 electrically connecting the doped region 40 or source/drain region and bit lines (not shown) formed thereafter and storage node contacts 26 electrically connecting the doped region 40 or source/drain region and capacitors fabricated in the later process.

Overall, an ion implantation process is preferably conducted to implant ions into the substrate 16 directly under the trench 28 to alter the surface property of the substrate 16 and then an ISSG process is conducted with controlled temperature and pressure parameters afterwards to form a gate dielectric layer 30 with uneven thickness on the surface of the trench 28. Specifically, the gate dielectric layer 30 formed within the trench 28 includes two thicknesses, in which the gate dielectric layer 30 above the bottom of the doped region 40 includes a first thickness 42 while the gate dielectric layer 30 below the bottom of the doped region 40 includes a second thickness 44 and the first thickness 42 is greater than the second thickness 44. Preferably, the design of uneven thickness of the gate dielectric layer 30 that includes a thicker gate dielectric layer 30 between the doped region 40 and the gate electrode 32 and a thinner gate dielectric layer 30 between the substrate 16 and the gate electrode 32 is able to effectively reduce the issue of gate-induced-drain-leakage (GIDL) in DRAM devices thereby boosting the performance of the device substantially.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. A method for fabricating semiconductor device, comprising:
forming a trench in a substrate;
performing an ion implantation process to implant ions into the substrate underneath the trench;
performing an in-situ steam generation (ISSG) process to form a gate dielectric layer in the trench;
forming a gate electrode on the gate dielectric layer; and
forming a doped region in the substrate adjacent to two sides of the gate electrode.

2. The method of claim 1, wherein the ion implantation process comprises implanting nitrogen ions or oxygen ions into the substrate.

3. The method of claim 1, wherein a temperature of the ISSG process is between 1000° C. to 1050° C.

4. The method of claim 1, wherein a pressure of the ISSG process is between 5 Torr to 20 Torr.

5. The method of claim 1, further comprising forming a hard mask on the gate electrode.

6. The method of claim 5, wherein a top surface of the hard mask is even with top surfaces of the gate dielectric layer and the substrate.

7. The method of claim 1, wherein the gate dielectric layer above the doped region comprises a first thickness and the gate dielectric layer under the doped region comprises a second thickness.

8. The method of claim 7, wherein the first thickness is greater than the second thickness.

9. A semiconductor device, comprising:
a gate electrode in a substrate;
a doped region in the substrate adjacent to two sides of the gate electrode; and
a gate dielectric layer between the gate electrode and the doped region, wherein the gate dielectric layer above the doped region comprises a first thickness and the gate dielectric layer under the doped region comprises a second thickness.

10. The semiconductor device of claim 9, further comprising a hard mask on the gate electrode.

11. The semiconductor device of claim 10, wherein a top surface of the hard mask is even with top surfaces of the gate dielectric layer and the substrate.

12. The semiconductor device of claim 9, wherein the gate electrode comprises:
a conductive layer on the gate dielectric layer; and
a metal layer on the conductive layer.

13. The semiconductor device of claim 12, wherein the conductive layer comprises titanium nitride (TiN).

14. The semiconductor device of claim 12, wherein the metal layer comprises tungsten (W).

15. The semiconductor device of claim 9, wherein the first thickness is greater than the second thickness.
